(19) United States
(12) Patent Application Publication
(10) Pub. No.: US 2008/0186671 A1
(43) Pub. Date: Aug. 7, 2008

(54) COOLING DEVICE OF HEATING ELEMENT AND AN ELECTRONIC DEVICE USING THE SAME

(76) Inventors: Yoshihiro KONDO, Tsuchiura (JP); Kenji Ogiro, Totsuka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/021,319

(22) Filed: Jan. 29, 2008

(30) Foreign Application Priority Data
Feb. 1, 2007 (JP) 2007-022542

(51) Int. Cl. H05K 7/20

(52) U.S. Cl. 361/687; 361/697

(57) ABSTRACT

In the electronic device such as computer and server which is operated in full day time and having high load condition in a limited time schedule, a suitable cooling device is provided for the heat generating elements which consists of the electronic device. The cooling device also has an feature to avoid the enlargement of the cooling device and have high power efficiency. The heat generated in the heat generating element is both transferred to a heat sink and a heat accumulator. The heat accumulator is also connected to the heat sink. The heat generating element and the heat accumulator is thermally connected by a heat pipe. And the heat accumulator and the heat sink is also thermally connected by another heat pipe.

### CLAIM OF PRIORITY

The present application claims priority from Japanese application serial No. 2007-22542 filed on Feb. 1, 2007, the content of which is hereby incorporated by reference into this application.

### BACKGROUND OF THE INVENTION

1. Field of the Invention

The present invention relates to a cooling device of heat generating elements and electronic device which uses the same.

2. Description of the Related Art

In recent years, according to the development of electronic devices to satisfy the high performance and multi function, the generation of heat in the circuit or circuit elements such as computer CPU, powered transistor etc. are increasing drastically. Therefore, the cooling capacity of the heat generating elements become very important factor for the performance of the electronic device.

The cooling of heat generating elements of an electronic device is performed generally by attaching a heat sink to the heat generating element and the heat sink is radiated naturally or forced to cool by the air flow of a cooling fan.

On the other hand, as the computer or server devices are running continuously the whole day, the performance varies in a wide range as to the time. Accordingly, the heat generated by the heat generating elements varies together with the performance. Therefore, for achieving the best performance of the cooling fan, the revolution speed of the cooling fan is controlled in relation to the heat of the heat generation element.

The cooling fan which is mounted in the electronic device has become enlarged to satisfy the heat generation of the maximum load mentioned above. This leads to enlarge the size of the electronic device and causes the waste of electronic power consumption. By the way, the high load condition is limited in a short time zone in an consecutive 24 running hours. Accordingly, it is difficult to solve the both problems of suitable cooling performance for the normal load and the proper cooling performance for maximum load.

Related to the above problem, a technique for averaging the cooling performance in a high and low load condition and avoiding the enlargement of the heat generating element cooling device are disclosed in Japanese Patent Laid-Open No. Hei 8-148618, Japanese Laid-Open No. 2004-342878 and Japanese Laid-Open No. 2006-147761.

Above mentioned cooling systems have the following technical problems. For example, the heat radiating structure described in Japanese Patent Laid-Open No. Hei 8-148618 thermally connects the heat generating element to both the heat accumulator and the heat sink directly and permanently. Further, the heat accumulator is also thermally connected to the heat sink.

In the structure, the heat generated from the heat generating element is transferred both to the heat sink and the heat accumulator for leveling the heat radiation. Accordingly, the cooling performance is not effective because a part of the heat, which could be radiated through the heat sink, is also accumulated to the heat accumulator uselessly.

In this related arts, a heat sink is thermally connected to the heat generating element and the heat accumulator is provided movably to the heat sink when the temperature of heat generating element rises, and heat accumulator is again moved back when the decreasing of the temperature of the heat generating element and cease the thermal connection form the heat sink. So, the increase of heat in the high load condition of the heat generating element is absorbed to the heat accumulator. And the enlargement of the heat sink and the enlargement of electronic device and increasing the electric energy consumption is evaded.

Accordingly, smooth heat conduction from the heat generating element is disturbed according to the heat generating condition of the heat generating element That is, both the gradual heat radiation from the heat accumulator and heat radiation from the heat generating element is performed under the normal load condition.

And in the related art, heat control is difficult because the release of the heat accumulator from the heat sink is decided not only by the temperature of the heat generating element, but also it is decided both the amount of generated heat both from the heat accumulator and heat generating element.

### SUMMARY OF THE INVENTION

The object of the invention is to provide a heat generating element cooling device and the electronic device using the cooling device, in which providing the heat conducting path from the heat generating element to both the heat sink and the heat accumulator, and further providing the heat conducting path from the heat accumulator back to the heat sink. In this way, this invention levels the cooling and heat radiation of the heat generating element to reduce the enlargement and the power consumption of the electronic device.

These object is achieved by providing a heat generating element cooling device for cooling the heat generating element made of circuit or circuit element of an electronic device, which is operated in a continuous predetermined time comprising:

a heat sink thermally connected to the heat generating element;

a heat accumulator;

a first heat conduction means thermally connected between the heat generating element and the heat accumulator and having the direction of heat conduction from the heat generating element to the heat accumulator; and

a second heat conduction means thermally connected between the heat accumulator and the heat sink and having the direction of heat conduction from the heat generating element to the heat accumulator.

These object is achieved by a method of controlling a cooling device for cooling the heat generating element made of circuit or circuit element of an electronic device, which is operated in a continuous predetermined time having a heat sink thermally connected to the heat generating element; a heat accumulator; a first heat conduction means thermally connected between the heat generating element and the heat accumulator and having the direction of heat conduction from the heat generating element to the heat accumulator; and a second heat conduction means thermally connected between the heat accumulator and the heat sink and having the direction of heat conduction from the heat generating element to the heat accumulator, the method have the steps of;

accumulating the exceeded heat of the heat generating element in a high load condition to the heat accumulator by the first heat transfer means,

transferring the heat of the heat accumulator in a ordinary load condition to the heat sink by the second heat transfer means,

and release the heat of the heat sink.

### BRIEF DESCRIPTION OF THE DRAWINGS

The invention will be more particularly described with reference to the following drawings.

FIG. 1 is a schematic diagram showing the server module mounted on a blade server according to an embodiment of the invention.

FIG. 2 is a schematic diagram showing the blade server according to the embodiment of the invention.

FIG. 3 is a schematic diagram showing the heat generating element cooling device mounted in the server module according to the embodiment of the invention.

FIG. 4 is a schematic curve showing the heat generating condition of the heat generating element according to the embodiment of the invention.

### DETAILED DESCRIPTION OF THE PREFERRED EMBODIMENTS

Next, the preferred embodiments of the present invention will be described referring to the accompanying drawings.

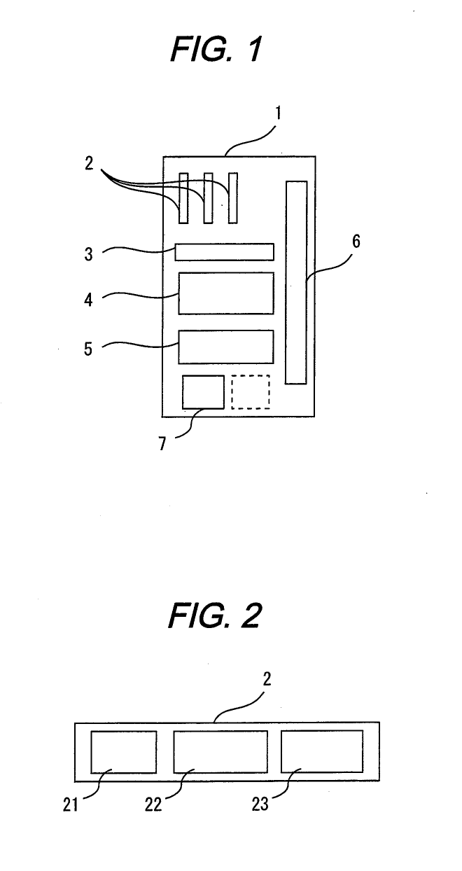

FIG. 1 is a schematic diagram showing the server module mounted on a blade server according to an embodiment of the invention.

In FIG. 1, 1 is a blade server. A plurality of server module 2 are provided on the blade server 1. 3 is a switch module. 4 is a management module. 5 is a network module. 6 is a cooling fan module. 7 is a power source module. FIG. 2 is a schematic diagram showing the blade server according to the embodiment of the invention. Server module 2 comprises basically a CPU 22, control circuit 21 and memory device 23.

In the embodiment, the heat generating element cooling means, which cool the heat generating element in the server module 2, also level the changing heat amount of the each heat generating element 22 mounted on the server module 2. Further, the cooling means can level the heat difference between each server module 2.

The blade server 1 have additional modules to the basic server modules to drive and control and integrate the plurality of server function and reduce the foot space and solve the complexity of network connection.

And the blade server 1 can be composed of an additional processor module or memory module. And it may omit some modules according to its purpose.

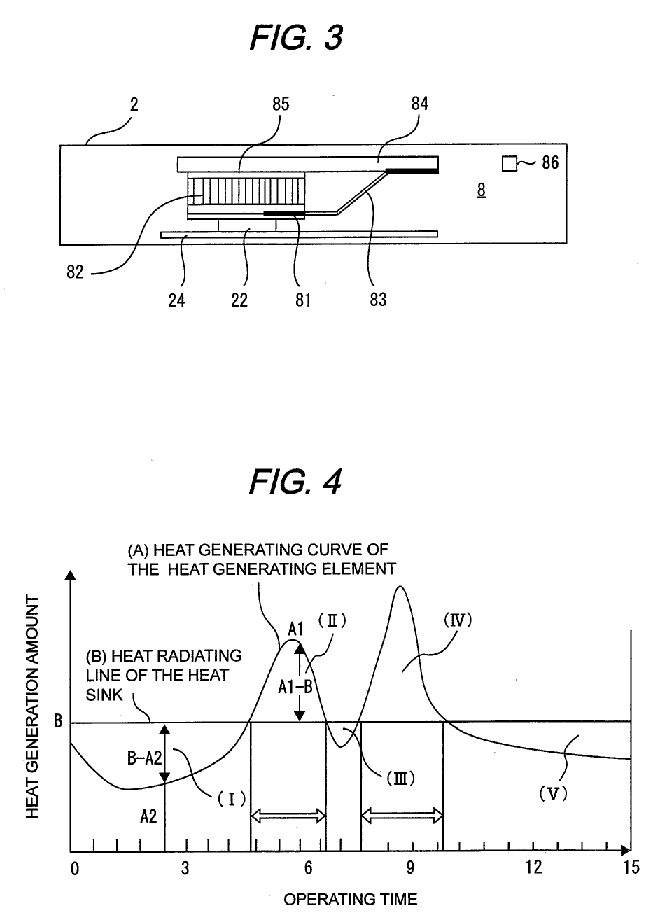

FIG. 3 is a schematic diagram showing the heat generating element cooling device 8 mounted in the server module 2 according to the embodiment of the invention. The structure of heat generating element cooling device 2 in the server module 2 is described below.

The cooling device cool the heat generating element 22 made of CPU in the server module 2. In the heat generating element cooling device 8, heat generating element 22 is thermally connected to the heat transmitting element 81 made of high heat conduction function such as Al or Cu. And the heat generating element 22 is also connected to the first heat conduction means made of heat pipe 83 which has the heat conduction direction from heat generating element 22 to the heat accumulator 84. The heat pipe 83 is thermally connected to the heat accumulator 84. The heat accumulator 84 is thermally connected to the heat sink 82 through the second heat conduction means composed of flat heat pipe 85 which has the direction of heat conduction from the heat accumulator 84 to the heat sink 82.

The flat heat pipe 85 can be replaced to a vapor chamber which is a type of a heat pipe having more high heat conductive efficiency. 86 is a accumulated heat measuring means composed of a remote temperature censor and calculating circuit which calculating the accumulated heat from the temperature and heat capacity of the heat accumulator 84.

FIG. 4 is a schematic curve showing the heat generating condition of the heat generating element in the typical operating condition of the server module 2. In FIG. 4, horizontal line means the operating time of the heat generating element 22 and vertical line shows the amount of generated heat of the heat generating element 22. The curve (A) thematically shows the change of an amount of heat generated by one of the heat generating element 22. The curve shows particularly when the range of change is large according to the time. The straight line (B) shows the average of the heat generating curve (A) and B is the average value.

The operation of heat generating element cooling device 8 in this embodiment is explained precisely using FIG. 3 and FIG. 4. In FIG. 4, the operative condition of heat generating element 22 rises from an normal load condition (I) to a first high load condition (II), and once returned to usual load condition (III), then again rises to the second high load condition (IV) and finally returned to a normal load condition (V).

The heat of heat generating element 22 is received by the heat conductive element 81 made of such as Al etc., then the heat is transferred to the heat sink 82 and radiated to the atmosphere. The maximum heat radiating capacity of the heat sink 82 is set equal to the average value B.

In that case, the amount of heat generated by the heat generating element 22 more than the average B can not be radiated by the heat sink 82 in the high load condition (II) and (IV). The excess heat not radiated by the heat sink 82 is conducted to the heat pipe through the heat conductive member 81 and transferred to the heat accumulator 84. The heat accumulator 84 has a sufficient heat capacity which accumulate the heat not radiated by the heat sink 82 at that time. The excess heat accumulated in the heat accumulator 84 more than the average B in the high load condition (II) and (IV) is radiated from the heat sink 82 in the normal load condition (I), (III) and (V). The radiated heat is equal to the differential between the average B and the heat generating curve (A) because the total amount of heat received and radiated by the heat accumulator 84 is the same.

Namely, the maximum heat radiating capacity of the heat sink 82 is decided equal to the average B of the heat generated by the heat generating element 22, and call the heat of the heat generating element 22 in a high load condition as Al. If the vaporing temperature of the coolant of heat pipe 83 is set equal to the temperature corresponding to the average B, the differential of heat (Al—B) is absorbed by the coolant and transferred by the heat pipe 83. The transferred heat is then accumulated to the heat accumulator 84. After that, the coolant of the heat pipe 83 is cooled by the heat accumulator 84 and condensed and returned to the original position.

Among the heat generated during the high load condition, the differential of heat (Al—B) accumulated by the heat accumulator 84 instead of directly radiating through the heat sink 82 is radiated through the heat sink 82 gradually. The heat radiated from the heat sink 82 is performed during the normal load condition (I), (III) and (V) and the radiated heat from the heat generating element 22 is reduced to value A2 which is under the average B.

The heat accumulator 84 is thermally connected to the heat sink 82 through the flat heat pipe 85. The operative temperature of the heat pipe 85 is set equal to the temperature corresponding to the differential of heat (Al—B) which is accumulated to the heat accumulator 84 in a high load condition. Then the coolant of the flat heat pipe 85 is vapored by the heat accumulated in the heat accumulator 84 and absorbs the differential of heat (Al—B). Accordingly, the differential of heat (B-A2) is transferred from the heat accumulator 84 to the heat sink 82 at the temperature corresponding to the radiated heat A2 of the heat sink 82 in the normal load condition. The heat is radiated from the heat sink 82 with the heat A2 of the heat generating element 22. After that, the coolant is condensed by the heat sink 82 and returned to the original position in the flat heat pipe 85.

Therefore, when the heat of the heat generating element 22 is greater than the average B, the differential of heat is accumulated in the heat accumulator 84. In the case the heat of the heat generating element 22 is smaller than the average B, the accumulated heat is radiated through the heat sink 82 according to its maximum heat radiating rate which is equal to the average B. In this way, the radiated heat from the heat sink 82 is leveled and the maximum of radiated heat is suppressed and consequently the enlargement of the heat sink 82 is restricted.

In the embodiment, the operating temperature of the heat pipe 83 and flat heat pipe 85 are set equal to the temperature corresponding to the maximum radiating heat capacity of the heat sink 82. However, to assure the stable operation of the cooling device, it is desirable to set the operating temperature of the heat pipe 83 more than the temperature corresponding to the maximum radiating heat capacity of the heat sink 82, and to set the operating temperature of the heat pipe 85 less than the temperature corresponding to the maximum radiating heat capacity of the heat sink 82.

In this case, the radiating of excess heat from the heat pipe 83 compared to the maximum radiated heat of the heat sink 82 is enforced by increasing the rotational speed of the cooling fan of the cooling fan unit 7 for rising the heat radiating efficiency of the heat sink 82.

In this embodiment, the maximum radiating heat of heat sink 82 is explained as equal to the average B of the heat generating element 22. Actually, it is preferable to set the maximum radiating heat is larger than the average B.

In this embodiment, the heat measuring means for measuring the heat transferred to the heat accumulator 82 is provided in the server module 2. According to the measuring result of the heat of the heat generating element 22 in a high load condition, the gradually radiating amount of heat is controlled in the time schedule. In this way, the air supply by the cooling fan to the heat sink 82 in the normal load condition can be suppressed and the reduction of the supply power consumption is achieved.

What is claimed is:

1. A heat generating element cooling device for cooling the heat generating element made of circuit or circuit element of an electronic device, which is operated in a continuous predetermined time comprising:
a heat sink thermally connected to the heat generating element;
a heat accumulator;
a first heat conduction means thermally connected between the heat generating element and the heat accumulator and having the direction of heat conduction from the heat generating element to the heat accumulator; and
a second heat conduction means thermally connected between the heat accumulator and the heat sink and having the direction of heat conduction from the heat generating element to the heat accumulator.

2. The heat generating element cooling device according to claim 1, further comprising:
the first heat conduction means has an operating temperature for transfer the heat of the heat generating element to the heat accumulator equal or above the temperature which correspond to the maximum amount of heat radiation of the heat sink; and
the second heat conduction means has an operating temperature for transfer the heat of the heat accumulator to the heat sink equal or above the temperature which correspond to the maximum amount of heat radiation of the heat sink.

3. The heat generating element cooling device according to claim 1, wherein the first heat conduction means is made of heat pipe and the second heat conduction means is made of heat pipe.

4. The heat generating element cooling device according to claim 3, wherein a cooling device is provided which remove the heat from the heat sink.

5. The heat generating element cooling device according to claim 3, wherein a cooling device is made of a cooling fan.

6. The heat generating element cooling device according to claim 4, wherein a heat accumulation measuring instrument is provided for measuring the accumulated heat of the heat accumulator, whereby a quantity of cooling value of the heat sink by the cooling device is controlled according to the measured heat accumulation of the heat accumulator.

7. The heat generating element cooling device according to claim 3, wherein the first heat conduction means is made of heat pipe and the second heat conduction means is made of flat heat pipe.

8. The heat generating element cooling device according to claim 3, wherein the first heat conduction means is made of heat pipe and the second heat conduction means is made of vapor chamber.

9. A method of controlling a cooling device for cooling the heat generating element made of circuit or circuit element of an electronic device, which is operated in a continuous predetermined time having a heat sink thermally connected to the heat generating element; a heat accumulator; a first heat conduction means thermally connected between the heat generating element and the heat accumulator and having the direction of heat conduction from the heat generating element to the heat accumulator; and a second heat conduction means thermally connected between the heat accumulator and the heat sink and having the direction of heat conduction from the heat generating element to the heat accumulator, the method have the steps of;
accumulating the exceeded heat of the heat generating element in a high load condition to the heat accumulator by the first heat transfer means,
transferring the heat of the heat accumulator in a ordinary load condition to the heat sink by the second heat transfer means,
and release the heat of the heat sink.

10. An electronic device, which is operated in a continuous predetermined time under the operating load condition varies, and having a heat generating element made of circuit or circuit element, the electronic device comprising:
a heat sink thermally connected to the heat generating element;
a heat accumulator;
a first heat conduction means thermally connected between the heat generating element and the heat accumulator and having the direction of heat conduction from the heat generating element to the heat accumulator; and
a second heat conduction means thermally connected between the heat accumulator and the heat sink and having the direction of heat conduction from the heat generating element to the heat accumulator;
wherein the heat of the heat generating element is radiated from the heat sink under normal load condition and both radiating the heat of the heat generating element from the heat sink and transfer the heat of the heat generating element to the heat accumulator by the first heat conduction means under high load condition.

11. A method of cooling an electronic device having the heat generating element made of circuit or circuit element of the electronic device which is operated in a continuous predetermined time and the load condition varies during the operation, in which the electronic device comprises a heat sink thermally connected to the heat generating element; a heat accumulator; a first heat conduction means thermally connected between the heat generating element and the heat accumulator and having the direction of heat conduction from the heat generating element to the heat accumulator; and a second heat conduction means thermally connected between the heat accumulator and the heat sink and having the direction of heat conduction from the heat generating element to the heat accumulator,
the method comprising the steps of;
transferring the excess heat of the heat generating element not released in the heat sink to the heat accumulator by the first heat conduction means under high load condition;
releasing the heat of the heat accumulator from the heat sink and radiating the heat of the heat generating element from the heat sink simultaneously under normal load condition;
controlling the air volume of the cooling fan according to the heat of the heat generating element under the normal load condition in which the heat amount is measured by the accumulated heat measuring means; and
releasing the heat of the heat accumulator through the heat sink for a predetermined time.
